(19) United States
(12) Patent Application Publication
(10) Pub. No.: US 2007/0004051 A1
(43) Pub. Date: Jan. 4, 2007

(54) Processing method and device

(76) Inventors: Yasuhiro Okumoto, IBARAKI (JP); Wataru Karasawa, Tokyo (JP)

Correspondence Address: FINNEGAN, HENDERSON, FARABOW, GARRETT & DUNNER, 1300 I STREET N.W., WASHINGTON, DC, 20005-3315, US

(21) Appl. No.: 10/539,246

(22) PCT Filed: Dec. 17, 2003
(86) PCT No.: PCT/JP03/16199

§ 371 Date: May 9, 2006

(30) Foreign Application Priority Data
Dec. 17, 2002 (JP) 20002-365777

(51) Int. Cl. H01L 21/00

(52) U.S. Cl. 438/5

(57) ABSTRACT

A processing system has a processing section for continuously processing a member to be processed; an inspection section for inspecting a processed state of the member processed by the processing section; a processed state determination section for determining whether the processed state is defective/nondefective, on the basis of a result of inspection performed by the inspection section; a continuity determination section for determining whether or not a defective determination is continuously made when the processed state is determined to be defective by the processed state determination section; and a processing control section for controlling processing so as to stop processing of the member continuously performed by the processing section when the continuity determination section determines that the defective determination is continuously made.

### TECHNICAL FIELD

The present invention relates to a processing method and a processing system for controlling processing through use of a sensor or the like.

### BACKGROUND TECHNIQUE

Various processing devices, such as a film growth apparatus, are used for manufacturing an electronic device such as a semiconductor device or a liquid-crystal display device. The processing system consecutively processes a member to be processed, such as a semiconductor substrate, and the processing operation is controlled through use of various sensors.

For instance, in relation to a plasma etching system, there has been developed a technique for determining an end point for etching through use of a sensor for detecting luminous intensity of a plasma (see, e.g., Patent Document 1). When a pattern of predetermined geometry fails to be formed after etching, the plasma etching system is determined to be in an anomalous state on the basis of, e.g., information about the geometry output from a sensor for measuring the geometry of a formed pattern, and control is applied to processing, such as a halt in operation of the etching system.

(Patent Document 1) JP-A-5-36644

As mentioned above, the various types of processing devices a are controlled on the basis of information output from sensors. However, in an actual processing environment, the information detected by the sensor includes “fluctuations” of some degree. Therefore, the detection accuracy of the sensors is not necessarily perfect, and there may be a case where the detected information is erroneous information.

For instance, the internal environment in the plasma atmosphere always fluctuates, for reasons of a nominal variation in high-frequency power, a fluctuation in the flow rate of a processing gas, a fluctuation in processing pressure, an increase in the temperature of the substrate attributable to a plasma, or the like. Even when a change in the luminous intensity of the plasma is monitored, there may be a case where the “fluctuation” hinders accurate detection of an end point.

When such erroneous information is used for controlling processing, the etching system induces an anomaly in pattern geometry or a like phenomenon. For example, when the anomaly is out of tolerance, the etching system is determined to be in an anomalous state by means of a geometry measurement sensor. In this case, if an anomaly has been detected only once, operation of the processing system is stopped, and an operator will perform inspection or the like.

However, the origin of the anomalous processing is a detection error attributable to accidental fluctuations. For this reason, the possibility of consecutive occurrence of such an anomaly in processing is low. Even if processing is continued, the processing system will operate normally. Alternatively, even when inspection is performed, a failure is not found. Accordingly, halting the operation of the processing system in such a situation results in extreme inefficiencies.

Plasma processing is performed within, for example, a vacuum vessel. When the processing system is halted, work must be performed after the vacuum vessel has been subjected to the atmosphere and again returned to vacuum. Hence, a great amount of time is consumed before recovery of operation. Moreover, the anomalous processing is not attributable to a failure in the sensor or the apparatus. Therefore, a stopping time and labor, which are required for inspection, are completely useless, and a great deal of production loss is induced. Particularly, a producer who is required to perform small-batch production of a variety of products desires to avoid occurrence of a useless stopping time, which would otherwise induce a decline in throughput.

In addition to a detection error in the sensor due to “fluctuations,” there may be a case where anomalous processing is performed even when a failure has not actually arisen in the apparatus. For instance, there may be a case where anomalous processing is performed for reasons of a change in the environment, such as the temperature of the atmosphere, even when processing is performed with the same recipe. Even in this case, processing is halted, in the same manner, at a point in time when the processing is determined to be anomalous.

However, such an anomaly usually has a low degree of continuity and can be recovered by means of changing a parameter or recipe of the apparatus from the outside. Therefore, stopping processing for reasons of occurrence of such anomalous processing is useless.

As mentioned above, even when anomalous processing has been detected once, operation of the related-art processing system is halted. Therefore, processing is halted even in the event of a processing anomaly having no continuity or a processing anomaly which can be addressed from the outside. Hence, there is a chance of failure to realize sufficiently high productivity of the apparatus.

In view of the above-described circumstances, the present invention aims at providing a highly productive processing method and a highly productive processing system.

### DISCLOSURE OF THE INVENTION

To achieve the above object, the present invention provides a processing method including: a processing step of continuously processing a member to be processed; an inspection step of inspecting a processed state of the member processed through the processing step; a processing state determination step of determining whether the processing state is defective or nondefective, on the basis of a result of inspection performed through the inspection step; a continuity determination step of determining whether or not defective determination is continuously made when the processed state has been determined to be defective through the processing state determination step; and a processing control step of controlling processing such that processing of the member continuously performed through the processing step is stopped when a defective determination is determined to have been continuously made through the continuity determination step.

Preferably, the processing method may further include a reinspection step of reinspecting the processed member; and an inspection state determination step of determining the inspected state determined through the inspection step, on the basis of a result of inspection performed through the reinspection step.

Preferably, the processing method may further include a defective level determination step of determining a defective level determined through the processing state determination step, wherein, when the defective state is determined to have reached a predetermined level in the defective level determination step, processing of the member continuously performed in the processing step is halted during the processing control step.

Preferably, when the defective determination is determined to continue in the continuity determination step, processing of the member continuously performed in the processing step may be temporarily suspended in order to await an external command for the processing control step; and continuous processing may be suspended in the processing control step in accordance with the external command.

Preferably, the processing method may further include a processing condition change step of performing control for changing conditions employed in the processing step to process the member when the defective determination has been determined to be continuously made in the continuity determination step.

The present invention provides a processing system including: a processing section for continuously processing a member to be processed; an inspection section for inspecting a processed state of the member processed by the processing section; a processed state determination section for determining whether the processed state is defective/nondefective on the basis of a result of inspection performed by the inspection section; a continuity determination section for determining whether or not a defective determination is continuously made when the processed state is determined to be defective by the processed state determination section; and a processing control section for controlling processing so as to stop processing of the member continuously performed by the processing section when the continuity determination section determines that the defective determination is continuously made.

Preferably, the processing system may further include a reinspection section for reinspecting the processed member; and an inspection state determination section for determining the inspected state determined by the inspection section, on the basis of a result of inspection performed through the reinspection section.

Preferably, the processing system may further include a defective level determination section for determining a defective level determined by the processing state determination section, wherein, when the defective level determination section determines that the defective state has reached a predetermined level, processing of the member continuously performed by the processing section is halted by the processing control section.

Preferably, when the continuity determination section determines that the defective determination is continuously made, processing of the member continuously performed by the processing section may be temporarily suspended for awaiting an external command for the processing control section; and continuous processing may be suspended by the processing control section in accordance with the external command.

Preferably, the processing system may further include a processing condition change control section which performs control for changing conditions employed by the processing system to process the member when the continuity determination section has determined that the defective determination is continuously made.

Further, the present invention provides a computer-readable recording medium with a program recorded thereon for controlling the processing system, having a processing section for continuously processing a member to be processed, and an inspection section for inspecting a processed state of a member processed by the processing section, wherein the program causes the computer to perform processing pertaining to a determination section for determining whether the processed state is defective/nondefective on the basis of a result of inspection performed by the inspection section; processing pertaining to a continuity determination section for determining whether or not a defective determination is continuously made when a defective state is determined in the processed state determination section; and processing pertaining to a processing control section for stopping processing of the member continuously performed by the processing section when the defective state is determined to have continued in the continuity determination section.

### BRIEF DESCRIPTION OF THE DRAWINGS

FIG. 1 is a view showing the configuration of a processing system according to an embodiment of the present invention;

FIG. 2 is a view showing the configuration of a processing chamber shown in FIG. 1;

FIG. 3 is a view showing the appearance of a wafer surface;

FIG. 4 is a view showing the configuration of a surface geometry measurement unit;

FIG. 5 is a view showing an example configuration of a library;

FIG. 6 is a view showing an operation flow;

FIG. 7 is a view showing a modification of the operation flow;

FIG. 8 is a view showing another modification of the operation flow;

FIG. 9 is a view showing still another modification of the operation flow;

FIG. 10 is a view showing yet another modification of the operation flow;

FIG. 11 is a view showing the configuration of a thermal oxidation system;

FIG. 12 is a view showing a side cross sectional profile of the thermal oxidation system;

FIG. 13 is a view showing the configuration of a film thickness measurement unit;

FIG. 14 is a block diagram showing the detailed configuration of a controller;

FIG. 15 is a block diagram showing a modification of the controller;

FIG. 16 is a view showing another modification of the controller; and

FIG. 17 is a view showing yet another modification of the controller.

Throughout the drawings, reference numeral 1 designates a processing system; 2 designates a module; 3 designates a transport chamber; 4 designates a processing chamber; 12 designates a geometry measurement unit; and 100 designates a controller.

### BEST MODE FOR IMPLEMENTING THE INVENTION

A processing method and a processing system, both pertaining to an embodiment of the present invention, will be described hereinbelow by reference to the drawings. The embodiment will be described by means of taking, as an example, an etching system which subjects a semiconductor wafer (hereinafter called a “wafer W”) to dry etching.

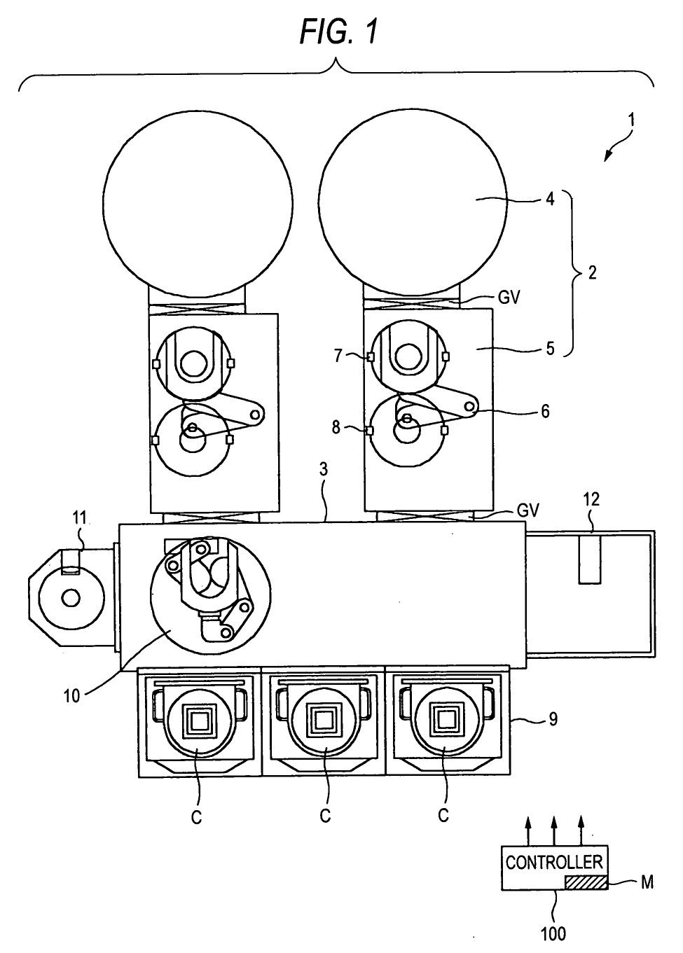

FIG. 1 shows the configuration of a processing system according to an embodiment. As shown in FIG. 1, a processing system 1 has a module 2 and a transport chamber 3.

The operation of the entire processing system 1 is controlled by a controller 100.

The module 2 has a processing chamber 4 for subjecting the wafer W to etching, and a load lock chamber 5 constituting a transport space to the processing chamber 4.

The processing chamber 4 and the load lock chamber 5 are separated from each other by means of a gate valve GV.

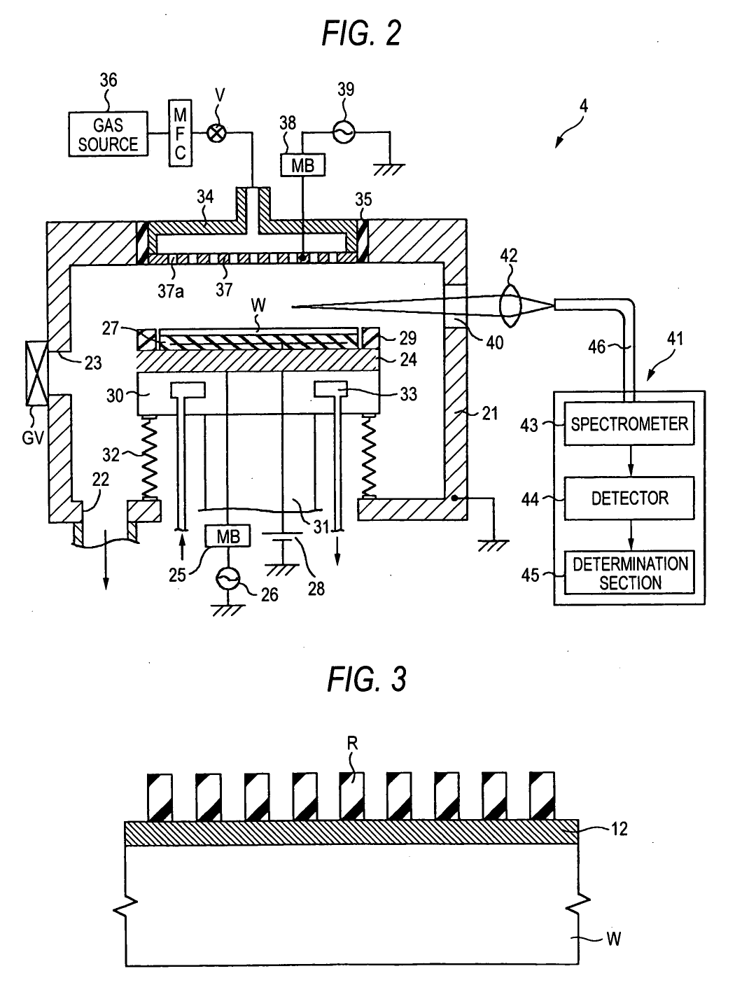

FIG. 2 shows the configuration of the processing chamber 4. As shown in FIG. 2, the processing chamber 4 has a substantially-cylindrical processing vessel 21. The processing vessel 21 is formed from, e.g., aluminum whose surface has been subjected to alumite treatment (anodic oxidation treatment). Further, the processing vessel 21 is connected to ground. An air outlet 22 is formed in the bottom of the processing vessel 21. The air outlet 22 is connected to an unillustrated exhaust system, thereby exhausting air from the processing vessel 21 to thus achieve a vacuum atmosphere.

A gate 23 is provided on the side wall of the processing vessel 21. The gate 23 is hermetically sealed by the gate valve GV. The wafer W is transported between the processing vessel 21 and the adjacent load lock chamber 5 with the gate valve GV open.

A disk-shaped susceptor 24 formed from conductive material such as aluminum is disposed in the internal center of the processing chamber 21. The susceptor 24 is connected to a first high-frequency power source 26 by way of a first matching device 25 and is configured so as to be able to apply high-frequency power. Applying power of predetermined frequency to the susceptor 24 constituting a lower electrode yields an advantage of efficient gathering of activated etching species.

An electrostatic chuck 27 is disposed on top of the susceptor 24. The electrostatic chuck 27 is formed by coating a disk-shaped metal thin plate connected to a d.c. power supply 28 with an insulating material such as ceramic or the like. The wafer W is placed on top of the electrostatic chuck 27. The wafer W is adsorbed by the electrostatic chuck 27 by means of electrostatic force in accordance with the d.c. voltage applied by the d.c. power source 28.

A focus ring 29 made of silicon, quartz, or the like is provided along a brim of an upper surface of the susceptor 24 so as to surround the outer periphery of the electrostatic chuck 27. The focus ring 29 is made of a conductive material or an insulating material and causes reactive ions to uniformly and effectively enter the wafer W.

The susceptor 24 is supported on a substantially-columnar susceptor support table 30. The susceptor support table 30 is secured to a shaft 31 which penetrates through the bottom of the processing chamber 21. The shaft 31 is connected to an unillustrated elevator mechanism and configured so as to be able to ascend or descend in conjunction with the susceptor 24 or the like.

A bottom of the susceptor support table 30 and the bottom of the processing vessel 21 are connected by means of an extensible bellows 32. During ascending/descending motion of the susceptor support table 30, the internal hermeticity of the processing vessel 21 is maintained.

A coolant channel 33 is provided within the susceptor support table 30. Coolant is circulated and flows through the coolant channel 33, whereby the susceptor support table 30 and surroundings thereof are held at a predetermined temperature.

A lift pin (not shown) for use in passing over and receiving the wafer W is provided to penetrate through the susceptor 24 and the electrostatic chuck 27 so as to be able to ascend or descend.

A shower head 34 is provided on top of the ceiling section of the processing vessel 21. The shower head 34 is insulated from the processing vessel 21 by means of an insulating substance 35. The shower head 34 is connected to a gas source 36 by way of a valve V and a mass flow controller (MFC). The shower head 34 is supplied, from the gas source 36, with a mixed gas (etching gas) containing gaseous additives such as fluorocarbon (CxFy) and an inert gas (Ar or the like), and oxygen, at a given flow rate. Incidentally, the fluorocarbon gas, the inert gas, and the gaseous additives may be supplied separately.

An electrode plate 37 is attached to the shower head 34. The electrode plate 37 is formed from aluminum or the like into the shape of a disk or a like shape. A plurality of gas apertures 37a remaining in communication with an internal hollow of the shower head 34 are provided in the electrode plate 37. After having been dispersed in the hollow space, the gas supplied to the shower head 34 is uniformly supplied to the inside of the processing vessel 21 by way of the plurality of gas apertures 37a.

The electrode plate 37 is connected to a second high-frequency power source 39 by way of a second matching device 38 and configured so as to be able to apply high-frequency power. The electrode plate 37 is provided so as to oppose, while oriented substantially parallel to, the susceptor 24 constituting a lower electrode, thereby constituting an upper electrode of a so-called parallel plate plasma generation mechanism.

During processing, while the inside of the processing vessel 21 is maintained to a predetermined degree of vacuum with a process gas, first high-frequency power of 2 MHz is applied to the susceptor 24, and high-frequency power of 60 MHz is applied to the electrode plate 37. At this time, as a result of application of high-frequency power to the electrode plate 37, a plasma of process gas is generated between the susceptor 24 and the electrode plate 37. By means of application of high-frequency power to the susceptor 24, particles, such as ions, in the plasma are drawn to the wafer W on the susceptor 24, whereby reactive ion etching is performed.

A window 40 formed from an optically-translucent material such as quartz is provided in a sidewall of the processing vessel 21. An end point detection section 41 is disposed outside of the window 40. The end point detection section 41 receives light of the plasma generated in the processing vessel 21 by way of the window 40, and detects an end point of etching from the intensity of light.

The end point detection section 41 has a condenser lens 42, aspectrometer 43, a detector 44, and a determination section 45.

The condenser lens 42 is disposed in the vicinity of the window 40, gathers the plasma light emitted from the inside of the chamber, and guides the light to an optical fiber 46.

The spectrometer 43 is connected to one end of the optical fiber 46, and the generated light having passed through the optical fiber is dispersed into a spectrum of given wavelength.

The detector 44 is formed from a photoelectric converter or the like, detects the light dispersed and reflected by the spectrometer 43, and outputs the light in the form of an analog signal. The signal output from the detector 44 is converted into a digital signal by means of an unillustrated converter after having been amplified by an unillustrated amplifier.

The determination section 45 captures a change in the intensity of light in a predetermined wavelength range by means of monitoring the light and performs appropriate computing operation as required, to thus determine the end point of etching.

Processing to be performed by the processing chamber 4 having the above-described configuration will now be described. First, the wafer W is transported into the processing vessel 21 by way of the gate 23, and placed on the susceptor 24. The wafer W is fixed by application of a d.c. voltage to the electrostatic chuck 27. After transport of the wafer W, the gate valve GV is closed, and the inside of the processing vessel 21 is depressurized to a predetermined degree of vacuum (process pressure).

Next, the etching gas is let into the processing vessel 21 at a given flow rate from the shower head 34. At this time, high-frequency power is applied to the electrode plate 37 and the susceptor 24. As a result, the plasma of the etching gas is generated within the processing vessel 21, and the activated etching species are gathered in the neighborhood of the surface of the wafer W. The activated etching species, such as fluorocarbon ions or radicals, etch a masked silicon oxide film on the surface of the wafer W.

Etching proceeds primarily as a result of the silicon oxide reacting with fluorocarbon and being removed in the form of silicon fluoride or carbon monoxide. The endpoint detection section 41 monitors the intensity of light of residues stemming from etching, thereby detecting the end point of etching.

The end point detection section 41 monitors the intensity of the light originated from, e.g., carbon monoxide. When generation of carbon monoxide, which is a residue, is stopped as a result of etching having reached an end point, the intensity of the light is diminished. The end point detection section 41 captures a decrease, to thus detect the end point of etching.

When the end point detection section 41 has detected an end point of etching, the controller 100 stops application of the high-frequency power, thereby halting supply of the etching gas. Next, the internal pressure of the processing vessel 21 is returned to the original level by means of purging the processing vessel with an inert gas such as a nitrogen gas. Application of the d.c. voltage to the electrostatic chuck 27 is halted, thereby releasing the wafer W from a fixed state. Subsequently, the gate valve GV is released, and the wafer W is transported. Processing to be performed by the process chamber 4 is now terminated.

Turning again to FIG. 1, the transport chamber 3 is formed into a rectangular shape, and a plurality of modules 2; e.g., two modules 2, are attached to one side surface of the chamber. In the respective modules 2, the above-described processing is performed concurrently. The modules 2 are connected to the transport chamber via the gate valves GV by way of ends of the load lock chambers 5 opposite to the process chambers 4. Thus, the modules 2 are removably attached to the transport chamber 3.

An unillustrated window is provided on the other side of the transport chamber 3, and a cassette stage 9 is provided in the vicinity of the window. A plurality of cassettes C are provided in the cassette stage 9, wherein each cassette C can house a plurality of wafers; e.g., 25 wafers W. Unprocessed or processed wafers W are housed in the cassettes C.

As shown in FIG. 3, an insulating film L, such as a silicon oxide film, is formed over the surface of the wafer W housed in the cassette C, and a patterned resist R is formed over the insulating film L. The resist R is formed into a predetermined pattern (e.g., a grating geometry). The insulating film L is etched in the process chamber 4 while the resist R is taken as a mask.

Turning again to FIG. 1, a second transport mechanism 10 of, e.g., scalar dual arm type, is provided within the transport chamber 3 for transporting the wafers W. The second transport mechanism 10 is provided so as to be movable in the longitudinal direction of the transport chamber 3.

A pre-alignment stage 11 is provided at one end of the transport chamber 3. Before being processed, the wafer W is subjected to pre-alignment in the pre-alignment stage 11.

The inside of the transport chamber 3 is set to, e.g., atmospheric pressure, and a down-flow of a purified air, nitrogen gas, or the like, is formed in the transport chamber.

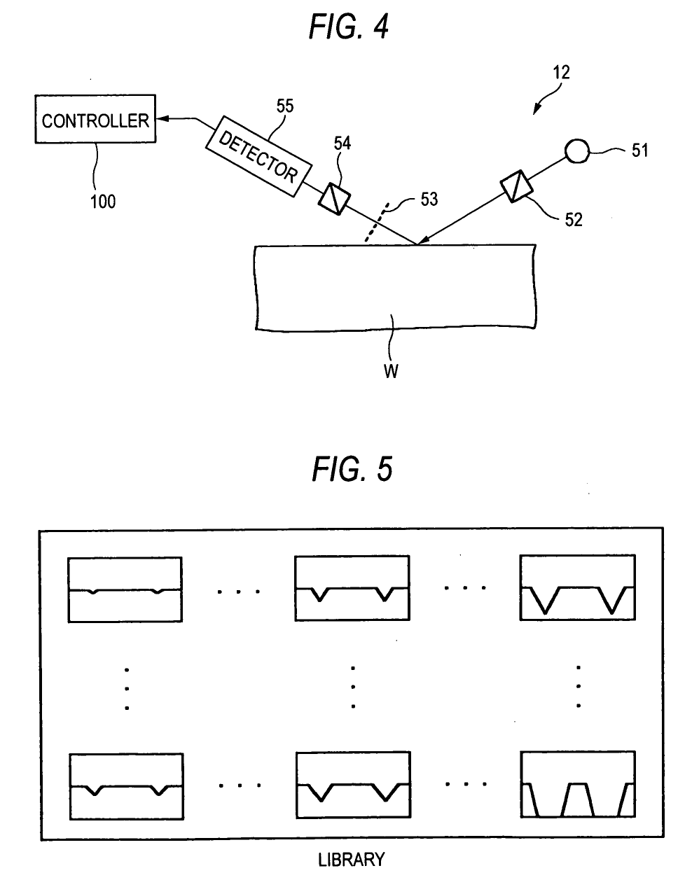

The geometry measurement unit 12 measures the surface geometry of the wafer W by means of a scatterometry technique using an ellipsometry technique. FIG. 4 shows the general configuration of the geometry measurement unit 12.

As shown in FIG. 4, the geometry measurement unit 12 has the configuration of a common ellipsometer and includes a light source 51, a polarizer 52, a compensator 53, an analyzer 54, and a detector 55.

The light source 51 causes white collimated light; e.g., a helium-neon laser beam, to enter the surface of the wafer W at a predetermined angle. An extra-high pressure mercury lamp or a xenon lamp is used as a light source, and white collimated light may be acquired by way of a collimator or a filter.

The polarizer 52 converts the collimated luminous flux emitted from the light source 51 into fully-linearly-polarized light. The linearly-polarized light having passed through the polarizer 52 is radiated onto the surface of the wafer W. The polarized state of the light reflected from the surface of the wafer W generally changes to oval polarized light.

The compensation plate 53 is formed from a quarter wavelength plate or the like and provided in an optical path of the light reflected from the wafer W. The compensation plate 53 converts the polarized oval light passing therethrough into linearly-polarized light.

The detector 55 is formed from a photodiode or the like and detects the light having passed through the analyzer 54.

The detector 55 is connected to a controller 100 by way of an unillustrated amplifier, an unillustrated analog-to-digital converter, or the like. A detection signal (output signal) detected by the detector is digitized and delivered to the controller 100.

The controller 100 acquires optical information about the surface geometry of the wafer W from the state of the polarized light stemming from the reflected light, by means of the scatterometry technique. As will be described later, the controller 100 controls the processing operation continuously performed by the processing system 1 on the basis of the received result of measurement.

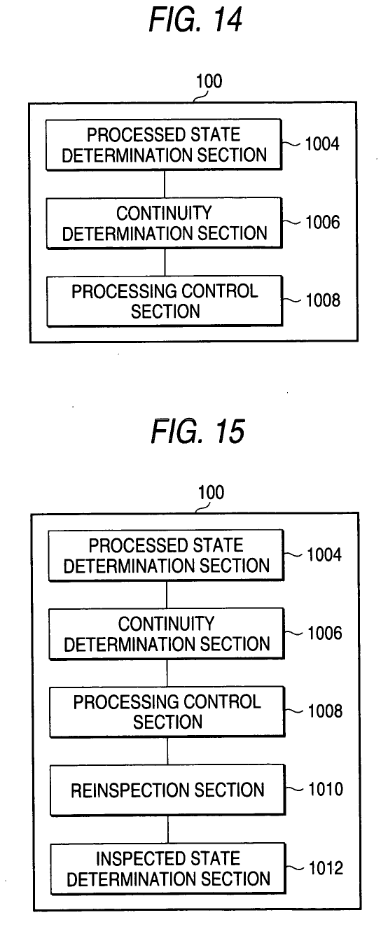

FIG. 14 is a view showing the configuration of the controller 100. As shown in FIG. 14, the controller 100 has a processed state determination section 1004 for determining whether the processed state of the wafer W is defective or nondefective on the basis of the result of measurement of the surface state of the processed wafer W acquired from the geometry measurement unit 12. The controller 100 has a continuity determination section 1006 for determining whether or not the defective determination is continuous when the processed state determination section 1004 has determined the processed state to be defective; and a processing control section 1008 for effecting control to stop processing of the wafer W continuously performed in the process chamber 4 when the defective determination is determined to be continues by the continuity determination section 1006.

Operation of the processing system 1 having the above configuration will be described hereunder. Operation provided below is an example, and whatever operation may be allowable, so long as a similar result is obtained.

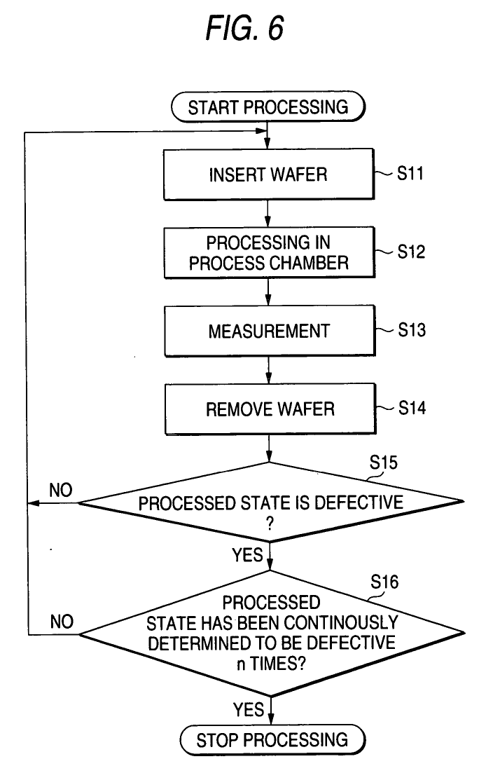

FIG. 6 shows the flow of processing operation of the processing system 1 according to the embodiment. First, the second transport mechanism 10 takes one unprocessed wafer W out of the cassette C placed on the cassette stage 9, and inserts the wafer into the transport chamber 3. After having the wafer W subjected to pre-alignment through use of the pre-alignment stage 11, the second transport mechanism 10 causes a first buffer 7 provided in the load lock chamber 5 to latch the wafer W.

After the second transport mechanism 10 has left, the gate valve GV that separates the load lock chamber 5 from the transport chamber 3 is closed, and the inside of the load lock chamber 5 is depressurized to a predetermined depressurized atmosphere. Subsequently, after the gate valve GV separating the load lock chamber 5 from the process chamber 4 has been released, the first transport mechanism 6 inserts the wafer W latched by the first buffer 7 into the process chamber 4 (step S1). After the first transport mechanism 6 has left, the gate valve GV is closed.

As mentioned above, the insulating film on the surface of the wafer W is subjected to etching within the process chamber 4 (step S12). After etching, the gate valve GV is released, and the first transport mechanism 6 takes the wafer W out of the process chamber 4, and a second buffer 8 of the load lock member 5 is caused to latch the wafer. After close of the gate valve GV that separates the load lock chamber from the process chamber 4 and after the load lock chamber 5 has been returned to a pressure level of the order of normal pressure, the gate valve GV separating the transport chamber 3 from the load chamber 3 is released.

Next, the second transport mechanism 10 takes the wafer W latched by the second buffer 8 to the transport chamber 3 and places the wafer at a predetermined position within the geometry measurement unit 12. By means of the above-described scatterometry technique, the geometry measurement unit 12 measures the surface geometry of the wafer W (step S13). After measurement, the wafer W is housed in the cassette C provided on the cassette stage 9 by means of the second transport mechanism 10 (step S14).

The processed state determination section 1004 of the controller 100 receives a result of measurement (optical information) from the geometry measurement unit 12, thereby determining whether the wafer W is defective or nondefective (step S15). The processed state determination section 1004 makes a determination by reference to, e.g., a library stored in memory M, external memory, or the like, as will be described below.

For example, cross-sectional profile (profile) data corresponding to optical information indicated by a surface geometry, such as those shown in FIG. 5, are stored in the library. A minute geometrical change can be detected with high accuracy by means of the ellipsometry method. A predetermined surface geometry and optical information indicated thereby correspond to each other in essentially a one-to-one relationship. Accordingly, a library of the cross-sectional geometry data corresponding to various optical information items are established as shown in FIG. 5, whereby the surface geometry of the measured wafer W can be ascertained.

The controller 100 has a reference library where are stored the geometry data used for determining a wafer W as a nondefective product, and checks the measured geometry data against the data in the reference library. When the measured profile does not match the data pertaining to the reference library (i.e., when the wafer is not in an allowable range), the wafer W is determined to be defective.

As a matter of course, when the optical information delivered from the geometry measurement unit 12 does not match any geometry data in the library (i.e., when the actual geometry is greatly different from the expected geometry), the wafer is determined to be defective, as well.

When the wafer is determined to be defective, the continuity determination section 1006 of the controller 100 determines whether or not the defective determination is continuously rendered “n” times (step S16). Here, “n” designates an integer of two or more; namely, when the defective determination is made only once, the controller 100 does not suspend the processing performed in the process chamber 4. the controller 100 performs counting operation every time a defective determination is continuously rendered. For example, the controller 100 performs continuous counting operations for each cassette C.

If the defective determination is not continuously rendered “n” times, the controller 100 returns to step S11, where processing is continued. Conversely, when the defective determination is determined to be continuously rendered “n” times, the processing control section 1008 of the controller 100 suspends processing of the wafer W performed by the process chamber 4. At this time, the controller 100 resets the count value. After halt of processing, only the process chamber 4 or the overall system is returned to the atmosphere according to the nature of the failure. The operator performs inspection or repair of the system.

As mentioned above, in the present embodiment, the controller 100 does not stop processing when a defective determination is rendered only once. Only when the defective determination is rendered continuously, the controller suspends processing. Accordingly, when anomalous processing having a low degree of continuity is performed as a result of the sensor, such as the end point detector 41 or the geometry measurement unit 12, having detected an error due to “fluctuations” in the measurement environment, stoppage of processing is avoided, so that an attempt can be made to enhance productivity.

In order to stop processing and perform inspection, there is required consumption of lots of efforts and much time, such as those required to change the internal atmosphere to the atmosphere and again return the internal atmosphere to the vacuum environment. However, when anomalous processing of low continuity, such as that mentioned above, has arisen, stoppage of processing is inefficient. Even when inspection or the like is performed, the anomaly is not attributable to a failure or the like. Therefore, the inspection will become totally useless.

The same also applies to a case where anomalous processing is performed with the same recipe for reasons of a change in the environment, such as the temperature of the atmosphere. Such anomalous processing usually has a low degree of chance to continue and can be addressed from the outside. Performing inspection, which involves stoppage of processing involves time and efforts, is inefficient and useless.

As a matter of course, when a failure or the like has actually arisen in the system, a defective determination will be made continuously, and hence processing is terminated. In this case, losses due to the failure are merely “n” wafers and the time required by the processing.

As mentioned above, according to the present embodiment where, when anomalous processing has arisen, processing is suspended after continuity of the anomalous processing has been ascertained, useless stopping time and efforts, which are required for inspection, can be eliminated, so that high productivity can be embodied.

The present embodiment can also assume modifications such as first to fourth modifications provided below.

(First Modification)

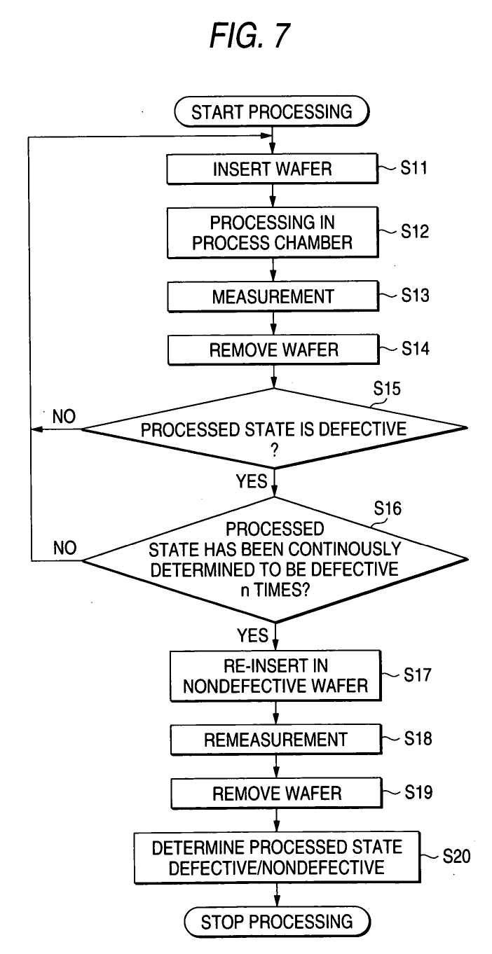

The previous embodiment is described on the assumption that processing is terminated when the processed state of the wafer is continuously determined to be anomalous “n” times. However, before processing is terminated, a determination may also be made as to whether or not the measurement performed by the geometry measurement unit 12 is normal. FIG. 7 shows an example operation flow employed in this case.

As shown in FIG. 7, when a failure has been continuously determined “n” times in step S16, a processed wafer W having determined to be nondefective is measured again. Specifically, the wafer W that has been processed before (n+1) or more wafers and determined to be nondefective is gain inserted into the transport chamber 3 (step S17). The surface geometry of the thus-inserted wafer W is again measured by the geometry measurement unit 12 (step S18). After measurement, the wafer W is taken out of the transport chamber 3 and housed in the cassette C (step S19).

The controller 100 determines whether the wafer W is defective or nondefective on the basis of remeasurement (step S20). Subsequently, processing is stopped.

When the wafer is determined to be nondefective through remeasurement, it is ascertained that the geometry measurement unit 12 performs measurement properly. As a result, the operator can consider the possibility of any anomaly having arisen in the process chamber 4, and can perform operation by omitting inspection of the geometry measurement unit 12.

Meanwhile, when the wafer W is determined to be defective, it is conceivable that any anomaly has arisen in the geometry measurement unit 12 because of the fact that a determination result differing from that obtained previously is obtained. In this case, the operator first inspects the geometry measurement unit 12 attached to the outside of the systemwithout releasing the vacuum environment in the system. When an anomaly in the geometry measurement unit 12 is found through inspection, the unit is repaired or exchanged. As mentioned above, since the operation is completed outside the system, the system can be simply recovered within a short period of time, so that an attempt can be made to enhance productivity.

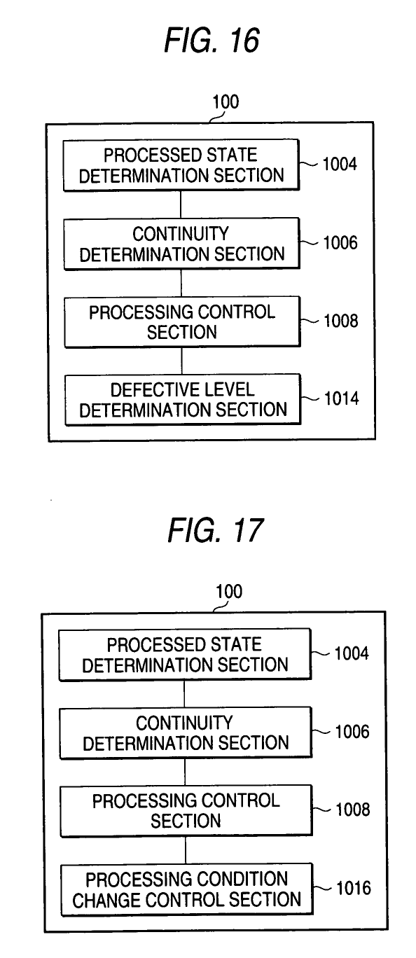

The step pertaining to the reinspection of the wafer W such as that mentioned above may be automatically performed by the controller 100. In this case, as shown in FIG. 16, the controller 100 may include a reinspection section 1010 for reinspecting the processed wafer W and an inspected state determination section 1012 for determining an inspected state determined by the geometry measurement unit 12 on the basis of an inspection result made by the reinspection section 1010, in addition to having the configuration shown in FIG. 14.

In step S20 shown in FIG. 7, as operation of the processing system 1 performed in this case, the reinspection section 1010 determines whether the wafer W, which is an object of reinspection, defective or nondefective, and the result of determination is output to the inspected state determination section 1012. When the reinspection section 1010 has output a determination result showing that the wafer W, which is an object of reinspection, is defective, the inspected state determination section 1012 determines that any anomalous has arisen in the geometry measurement unit 1012 and outputs the result to the operator. The operator inspects the geometry measurement unit 12 on the basis of an output from the inspected state determination section 1012.

(Second Modification)

The previous embodiment is described on the assumption that processing is stopped when a defective determination is continuously made “n” times. However, processing may also be stopped at a point in time when a serious failure is detected without awaiting the defective determination is continuously made “n” times.

In this case, as shown in FIG. 16, the controller 100 has a defective level determination section 1014 for determining a defective level determined by the processed status determination section 1004, in addition to having the configuration shown in FIG. 14.

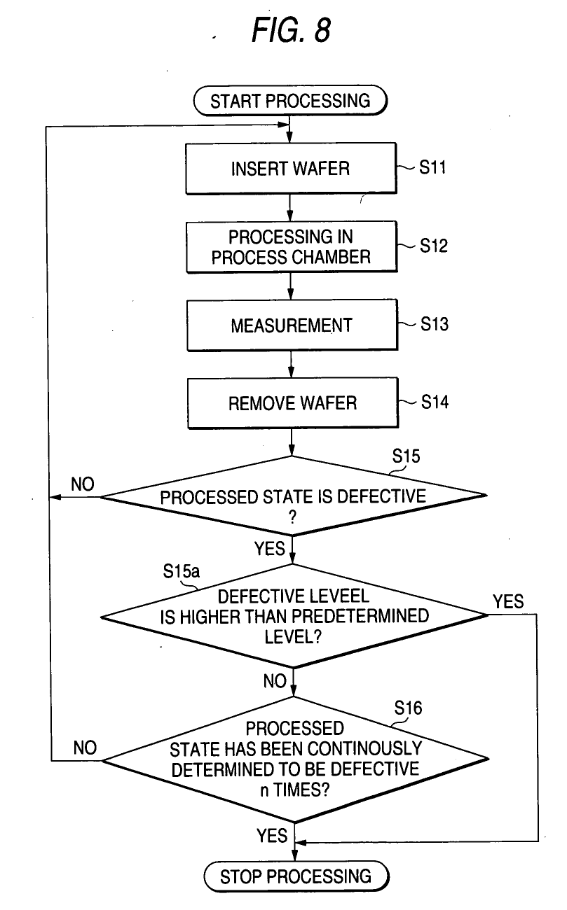

FIG. 8 shows an example operation flow.

As shown in FIG. 8, when a defective determination is made in step S15, the defective level determination section 1014 of the controller 100 determines whether or not the defective level is a predetermined level or higher (step S15a). On the basis of the result of measurement determined by the geometry measurement unit 12, the defective level determination section 1014 compares the geometry read from the library with the preset reference geometry in a superimposed manner. The defective level 1014 determines the extent to which the measured geometry deviates from the reference geometry. When the measured geometry deviates from the reference geometry by a predetermined level or more, the processing control section 1008 of the controller 100 immediately stops processing even when the defective determination is not continuously made “n” times.

A failure based on an erroneous detection, such as “fluctuations,” is usually expected to be less serious. As mentioned above, the degree of defectiveness is determined. When the defectiveness is determined to be less serious, processing is continued. In contrast, when the defectiveness is determined to be serious, processing is stopped, whereupon an anomaly, which would become serious, can be immediately addressed.

(Third Modification)

The previous embodiment is described on the assumption that processing is halted when a defective determination is continuously made. However, processing conditions of the processing chamber 4 may be altered without halting the processing.

In this case, as shown in FIG. 17, the controller 100 has a processing condition change control section 1016 which changes conditions employed for processing the wafer W in the process chamber 4, in addition to having the configuration shown in FIG. 14.

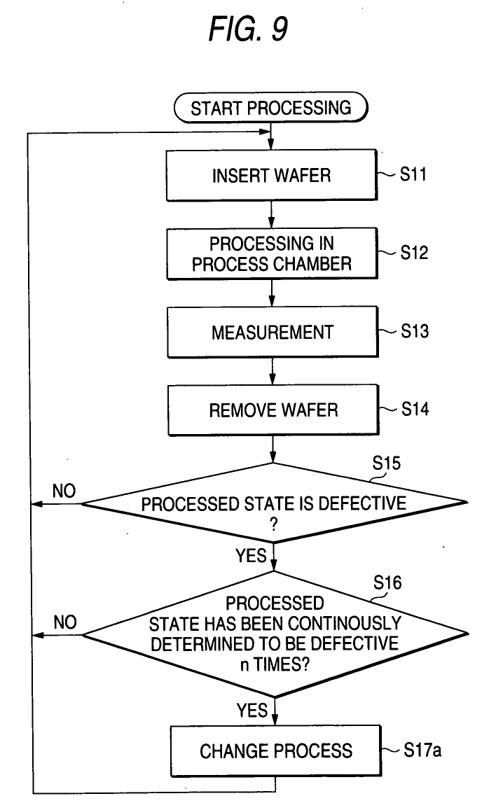

An example operation flow required in this case is shown in FIG. 9. As shown in FIG. 9, when a defective determination is determined to be continuously made “n” times in step S16, the processing condition change control section 1016 of the controller 100 changes the processing conditions of the process chamber 4 (step S17a). Processing conditions are changed in accordance with a change in system parameters or a recipe, e.g., a process temperature, applied power, or a gas flow rate. For instance, the controller 100 may be provided with a program for optimizing the system parameters in the event of occurrence of anomalies.

Such a change in the process is effective, e.g., when the once-stopped system is again started up. Namely, there may be a case where the same result is not yielded during startup of the system depending on the environment (a temperature or the like) where the system is installed even when processing is performed according to the same recipe, and, as a result, anomalous processing is performed. In such a case, the anomalous processing can be addressed without stopping processing by changing process conditions, thereby eliminating a waste, such as stoppage of operation of the system.

(Fourth Modification)

The previous embodiment is described on the assumption that any anomaly in the processing system 1 is detected. However, a configuration for detecting an anomaly in a preceding step; that is, a step of forming a resist mask, is also feasible.

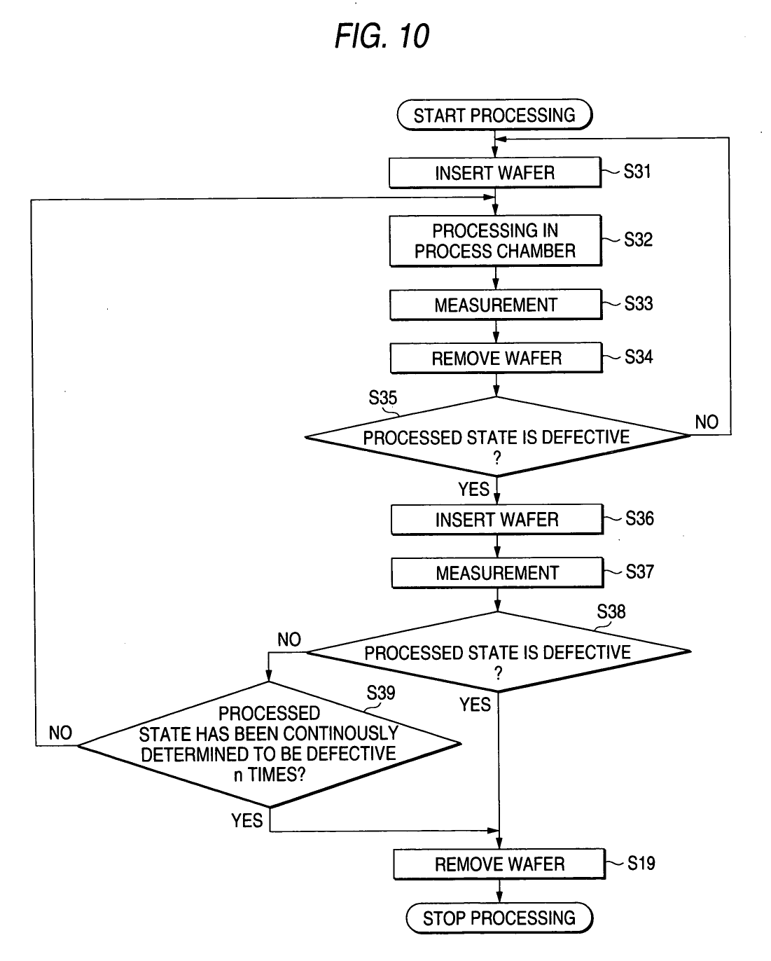

FIG. 10 shows an example flow employed in this case. In FIG. 10, steps S31 to S34 are the same as steps S11 to S14. When the wafer W is determined to be defective in step S35, a new unprocessed wafer W is inserted into the transport chamber 3 (step S36). Next, in contrast with ordinary processing, the wafer W is sent to the geometry measurement unit 12, where the wafer is measured (step S37).

The controller 100 also has a library, such as that shown in FIG. 5, in connection with the surface geometry of the unprocessed wafer W, and acquires surface geometry information from the optical information obtained from the geometry measurement unit 12 by reference to the library. The controller 100 makes a determination as to whether the wafer is defective or nondefective, as in the case of a determination is made as to the previously-described processed wafer W (step S38).

When the inserted wafer W is determined to be nondefective, a determination is made as to whether or not the defective determination is made continuously “n” times in step S35 in the same manner as mentioned above (step S39). In this case, no anomaly exists in the inserted wafer W, and the possibility of occurrence of an anomaly in the preceding step (formation of a resist film) is accordingly eliminated. Consequently, the current anomaly is considered to have arisen in the etching step. The number of times the anomaly has continuously arisen is determined in the same manner as mentioned previously. When the anomaly has not arisen continuously “n” times, processing returns to step S32 and is continued. When the anomaly is not continued “n” times, the wafer W is transported (step S40), and processing is terminated.

In contrast, when the wafer W is determined to be defective in step S38, the wafer W is removed (step S40), and processing is terminated. In this case, an anomaly is considered to have arisen in the preceding step, and continuation of processing is useless.

As mentioned above, the unprocessed wafer W as well as the processed wafer are subjected to a determination as to a defective/nondefective product, whereby a time in point when an anomaly has arisen can be specified more accurately, and an improvement in productivity, which would otherwise be induced by efficient recovery operation or the like, becomes possible.

The first through fourth modifications may be combined together.

The processing operation of the embodiment and those of the first through fourth modifications may be selectively indicated by the operator. For example, the operator inputs the number of times “n” at the outset of processing, and selectively inputs any of the operation of the embodiment and those of the first through fourth modifications. Alternatively, when the defective determination is made continuously “n” times, the controller 100 may suspend processing, issue an alarm to the operator, and await selective input of operation which would be performed by the operator.

Moreover, in the embodiment, processing analogous to that performed by the geometry measurement unit 12 may be performed in connection with measurement (detection of an end point) performed by the end point detector 41. For example, in the fourth modification, when the endpoint detector 41 cannot detect an end point; that is, when the end point detector fails to measure light of predetermined wavelength despite an attempt being made many times, a defective (or anomalous) determination is made. When such a determination is continuously made “n” times, the unprocessed wafer W may be sent to the geometry measurement unit 12, where a determination is made as to whether the wafer is defective or nondefective. Even in this case, the cause of the defectiveness is attributable to an anomaly in the processing system 1 or an anomaly in the wafer W to be processed.

In the embodiment, detection of an end point and measurement of the surface of the wafer W are performed by means of an optical technique. However, the measurement method is not limited to the above embodiment. For instance, a determination may be made as to whether the wafer W is defective or nondefective, by means of SEM or an electrical technique, in accordance with processing.

In the embodiment, the controller 100 is assumed to read the geometry data corresponding to the optical information acquired by reference to the library. However, a control section which independently performs such an analytical operation and has a CPU, memory, or the like, may be interposed between the geometry measurement unit 12 and the controller 100.

The embodiment has been described by taking the etching system as an example. However, the present invention is not limited to the etching system but can be applied to any system, such as a film growth system, an annealing system, a heat treatment system, a diffuser, a pre-exposure system, a post-exposure system, or the like.

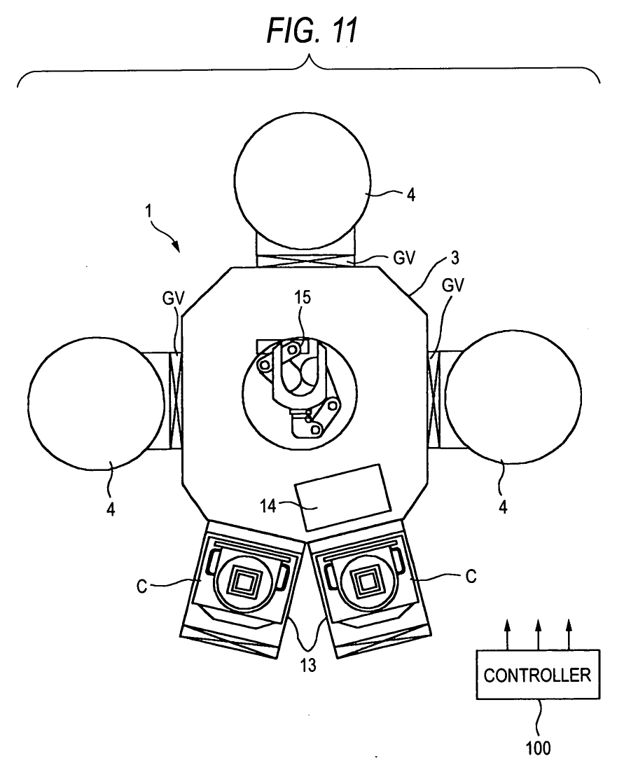

An example in which the present invention is applied to a thermal oxidation furnace. FIG. 11 shows the configuration of the processing system 1 constituting the thermal oxidation furnace. In order to facilitate comprehension, the configuration shown in FIG. 11, which is the same as that shown in FIG. 1, is given the same reference numeral, and its explanation is omitted.

The illustrated processing system 1 has a configuration in which a plurality of process chambers 4 are jointed to the transport chamber 3 in a cluster. In the illustrated configuration, the cassettes C are housed in the cassette chamber 13 which can be hermetically depressurized. A silicon oxide film is formed over the surface of the wafer W by means of thermal oxidation within the process chamber 4.

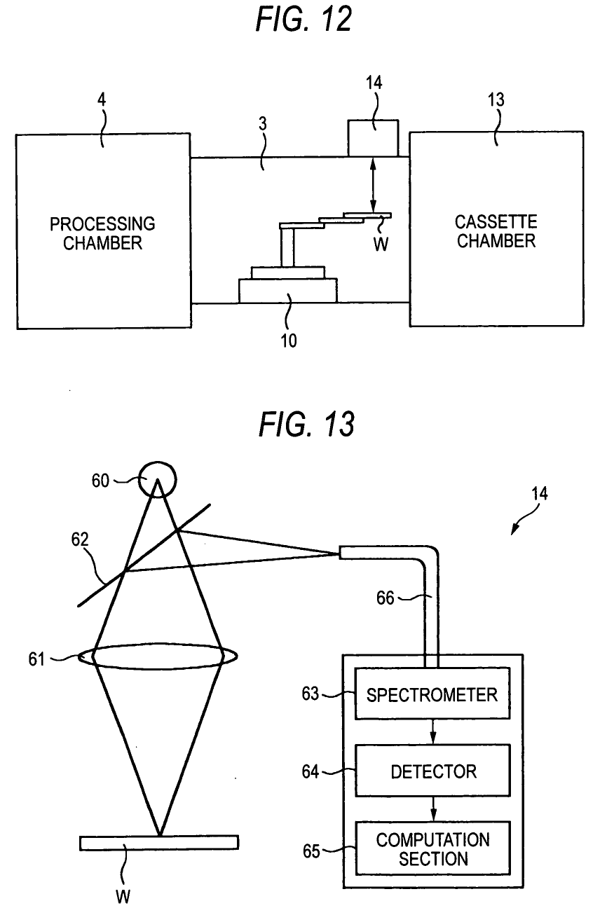

The transport chamber 3 is provided with a film thickness measurement unit 14 which measures the thickness of a film grown in the process chamber 4. As shown in FIG. 12, for instance the film thickness measurement unit 14 projects light on the wafer W held in a predetermined measurement position by a transport mechanism 15 on the ceiling of the transport chamber 3 or is situated at a position where the unit can receive light from the wafer W.

FIG. 13 shows the configuration of the film thickness measurement unit 14. As shown in FIG. 13, the film thickness measurement unit 14 includes a light source 60, a lens 61, a beam splitter 62, a spectrometer 63, a detector 64, and a computation section 65.

The light source 60 oscillates light of predetermined wavelength range.

The lens 61 is disposed in an optical path extending from the light source 60 to the wafer W. The light originating from the light source 60 is collimated or condensed as a result of having passed through the lens 61, and is radiated on a predetermined position on the surface of the wafer W.

The thus-radiated light is reflected from the surface of the wafer W and condensed by the lens 61. The reflected light is coherent light consisting of the light reflected from the surface of the oxide film and the light reflected from a boundary surface below the oxide film.

The beam splitter 62 is provided in the optical path of the reflected light having passed through the lens 61. The reflected light is split by the beam splitter 62 and guided to an optical fiber 66.

The spectrometer 63 is connected to one end of the optical fiber 66 and divides the reflected light having passed through the spectrometer into a spectrum of predetermined wavelength.

The detector 64 is formed from a photoelectric converter or the like, detects the reflected light divided into a spectrum by the spectrometer 63, and outputs the detected light as an analog signal. The signal output from the detector 64 is amplified by an unillustrated amplifier and converted into a digital signal by means of an unillustrated analog-to-digital converter.

The computation section 65 receives the digital signal showing the coherent reflected light as an input and determines the film thickness on the basis of the input. The computation section 65 analyzes the frequency of the interference waveform of the signal through use of a predetermined waveform analysis method (e.g., the maximum entropy method). The computation section 65 computes the film thickness on the basis of the frequency distribution of the interference wave.

For instance, the controller 100 determines a difference between the measured film thickness and a predetermined value, thereby determining whether or not the difference falls within a predetermined range. When the difference falls within the predetermined range, the wafer W is determined to be nondefective. When the difference falls outside the predetermined range, the wafer is determined to be defective. When having determined the wafer to be nondefective, the controller 100 continues processing.

The thermal oxidation furnace having the foregoing configuration is caused to perform any of the operation of the embodiment and the operations of the first through fourth modifications, thereby enabling performance of processing with high productivity.

The case where the wafer W is process has been described by means of the above-described case. However, the invention can also be applied to a case where any article such as liquid-crystal display substrate or the like is processed.

As a matter of course, the present invention can be applied to a processing system which continuously performs processing while performing inspection of a processed state.

The processing method according to the present invention can be embodied through use of an ordinary computer without involvement of configuration of a custom-designed system. For instance, a program for causing a computer to perform the above-described operations is installed from a medium (a flexible disk, a CD-ROM, a DVD-ROM, or the like) where the program is stored, whereby the above-described processing can be performed. The program is stored in a medium, such as a hard disk drive set in a computer, by means of installing operation, and put into execution.

Further, the medium used for supplying the program to the computer is not limited to a storage medium in a narrow sense but may be a storage medium, in a broad sense, including a communications medium for temporarily retaining information, such as a program, in the manner of flux as in the case of a communications line, a communications network, or a communications system.

For instance, the program may be registered in an FTP (File Transfer Protocol) server set in an communications network such as the Internet and delivered to an FTP client by way of the network. Alternatively, the program may be registered in an electronic bulletin board (BBS: Bulletin Board System) of the communications network or the like and delivered by way of the network. The above-described processing can be executed by means of launching the program under control of an OS (Operating System). Moreover, the program is initiated while being transferred over the communications network, whereby the above-described processing can be executed as well.

As mentioned above, the present invention has been described in detail or by reference to the specific embodiment. However, it is manifest for those skilled in the art to be able to make various alterations or modifications to the present invention without departing from the scope and range of the present invention.

The present invention is based on Japanese Patent Application (JP-A-2002-365777) filed on Dec. 17, 2002 and incorporated herein by reference.

### INDUSTRIAL APPLICABILITY

As has been described, the present invention can be applied to a processing system which continuously performs processing while performing an inspection of a processed state; for example, an etching system, a film growth system, an annealing system, a heat treatment system, a diffuser, a pre-exposure processing system, a post-exposure processing system, or the like.

1. A processing method comprising:
a processing step of continuously processing a member to be processed;
an inspection step of inspecting a processed state of said member processed through said processing step;
a processing state determination step of determining whether said processing state is defective or nondefective, on the basis of a result of inspection performed through said inspection step;
a continuity determination step of determining whether or not defective determination is continuously made when said processed state has been determined to be defective through said processing state determination step; and
a processing control step of controlling processing such that processing of said member continuously performed through said processing step is stopped when a defective determination is determined to have been continuously made through said continuity determination step.

2. The processing method according to claim 1, further comprising:
a reinspection step of reinspecting said processed member; and
an inspection state determination step of determining said inspected state acquired through said inspection step, on the basis of a result of inspection performed through said reinspection step.

3. The processing method according to claim 1, further comprising:
a defective level determination step of determining a defective level determined through said processing state determination step, wherein, when said defective state is determined to have reached a predetermined level in said defective level determination step, processing of said member continuously performed in said processing step is halted during said processing control step.

4. The processing method according to claim 1, wherein, when said defective determination is determined to continue in said continuity determination step, processing of said member continuously performed in said processing step is temporarily suspended in order to await an external command for said processing control step, and
wherein the continuous processing is suspended in said processing control step in accordance with said external command.

5. The processing method according to claim 1, further including a processing condition change step of performing control for changing conditions employed in said processing step to process said member when said defective determination has been determined to be continuously made in said continuity determination step.

6. A processing system comprising:
a processing section for continuously processing a member to be processed;
an inspection section for inspecting a processed state of said member processed by said processing section;
a processed state determination section for determining whether said processed state is defective/nondefective on the basis of a result of inspection performed by said inspection section;
a continuity determination section for determining whether or not a defective determination is continuously made when said processed state is determined to be defective by said processed state determination section; and
a processing control section for controlling processing so as to stop processing of said member continuously performed by said processing section when said continuity determination section determines that said defective determination is continuously made.

7. The processing system according to claim 6, further comprising:
a reinspection section for reinspecting said processed member; and
an inspection state determination section for determining said inspected state determined by said inspection section, on the basis of a result of inspection performed through said reinspection section.

8. The processing system according to claim 6, further comprising: a defective level determination section for determining a defective level determined by said processing state determination section, wherein, when said defective level determination section determines that said defective state has reached a predetermined level, processing of said member continuously performed by said processing section is halted by said processing control section.

9. The processing system according to claim 6, wherein, when said continuity determination section determines that said defective determination is continuously made, processing of said member continuously performed by said processing section is temporarily suspended for awaiting an external command for said processing control section, and
wherein the continuous processing is suspended by said processing control section in accordance with said external command.

10. The processing system according to claim 6, further comprising a processing condition change control section which performs control for changing conditions employed by said processing system to process said member when said continuity determination section has determined that said defective determination is continuously made.

11. A computer-readable recording medium with a program recorded thereon for controlling said processing system, having a processing section for continuously processing a member to be processed, and an inspection section for inspecting a processed state of a member processed by said processing section, the program causing said computer to perform processing comprising:
a processing state determination step of determining whether said processing state defective or nondefective on the basis of a result of inspection performed by said inspection section;
a continuity determination step of determining whether or not defective determination is continuously made when said processed state has been determined to be defective through said processing state determination step; and
a processing control step of controlling processing such that processing of said member continuously performed through said processing step is stopped when a defective determination is determined to have been continuously made through said processing section.
